(19) United States
(12) Patent Application Publication
(10) Pub. No.: US 2019/0280148 A1
(43) Pub. Date: Sep. 12, 2019

(54) SEMICONDUCTOR LIGHT RECEIVING DEVICE

(71) Applicant: SUMITOMO ELECTRIC INDUSTRIES, LTD., Osaka (JP)

(72) Inventors: Sundararajan BALASEKARAN, Osaka (JP); Hiroshi INADA, Osaka (JP)

(73) Assignee: SUMITOMO ELECTRIC INDUSTRIES, LTD., Osaka (JP)

(21) Appl. No.: 16/293,010

(22) Filed: Mar. 5, 2019

(30) Foreign Application Priority Data
Mar. 7, 2018 (JP) 2018-040849

(51) Int. Cl. H01L 31/12; H01L 31/0304; H01L 31/0352

(52) U.S. Cl. CPC H01L 31/12; H01L 31/035281; H01L 31/035236; H01L 31/0304

(57) ABSTRACT

A semiconductor light receiving device includes a supporting base having an n-type semiconductor region; and a photodiode structure disposed on the supporting base. The photodiode structure includes a barrier structure enabling an electron barrier, a light absorbing layer including III-V compound semiconductor, and a p-type semiconductor region. The III-V compound semiconductor of the light absorbing layer has a bandgap allowing the light absorbing layer to be sensitive to infrared light. The barrier structure includes a first spacer layer, a first barrier layer, and a second spacer layer, and the p-type semiconductor region, the light absorbing layer, the first spacer layer, the first barrier layer, the second spacer layer, and the n-type semiconductor region are sequentially arranged along a direction of a first axis.

### BACKGROUND OF THE INVENTION

### Field of the Invention

The present invention relates to a semiconductor light receiving device. This application claims the benefit of priority from Japanese Patent application No. 2018-040849 filed on Mar. 7, 2018, which is herein incorporated by reference in its entirety.

### Related Background Art

“Band engineered HOT mid wave infrared detectors based on type-II InAs/GaSb strained layer superlattices”, Infrared Physics & Technology, Elsevier, 2013, referred to as Non-patent document 1, discloses an infrared detector having a type II superlattice.

### SUMMARY OF THE INVENTION

A semiconductor light receiving device according to one aspect of the present embodiment includes a supporting base including an n-type semiconductor region; and a photodiode structure disposed on the supporting base, the photodiode structure including a barrier structure, a light absorbing layer, and a p-type semiconductor region. the light absorbing layer including III-V compound semiconductor, the III-V compound semiconductor of the light absorbing layer having a bandgap allowing the light absorbing layer to be sensitive to infrared light, the barrier structure including a first spacer layer, a first barrier layer, and a second spacer layer, the barrier structure enabling an electron barrier, and the p-type semiconductor region, the light absorbing layer, the first spacer layer, the first barrier layer, the second spacer layer, and the n-type semiconductor region being arranged in order along a direction of a first axis.

### BRIEF DESCRIPTION OF THE DRAWINGS

The above-described objects and the other objects, features, and advantages of the present invention become more apparent from the following detailed description of the preferred embodiments of the present invention proceeding with reference to the attached drawings.

FIG. 1 is a schematic view showing the laminate structure and the band diagram of a semiconductor light receiving device according to the embodiment.

FIG. 2A is a schematic plan view illustrating the semiconductor light receiving device shown in FIG. 1.

FIG. 2B is a schematic cross-sectional view, taken along line IIb-IIb in FIG. 2A, illustrating the semiconductor light receiving device shown in FIG. 1.

FIG. 3 is a diagram illustrating an exemplary band structure in the semiconductor light receiving device according to the embodiment.

FIG. 4 is a schematic view showing the barrier structure, and potential curves therein that vary depending upon the voltage on the control electrode, connected with a measurement circuit, of the semiconductor light receiving device according to the embodiment.

FIG. 5A is a schematic view showing a photodiode structure and a band diagram in one experimental example.

FIG. 5B is a schematic view showing a photodiode structure and a band diagram in another experimental example.

FIG. 6 is a view showing the dark current characteristics of the semiconductor light receiving devices C and D, which are shown in FIGS. 5A and 5B, respectively.

FIG. 7 is a view showing the dark current characteristics DC and the photo response characteristics PC of the semiconductor light receiving device D according to the embodiment.

FIG. 8 is a view showing waveforms of the voltages (VCNT) and (VOUT), applied to the control electrode and across the anode and the cathode of the semiconductor photodetector D according to the embodiment, respectively, in the measurement system of FIG. 7.

### DESCRIPTION OF THE PREFERRED EMBODIMENTS

An infrared detector including a type-II superlattice light absorbing layer should be used at low temperatures which allow the detector to exhibit a low dark current, for example, at a temperature of 77 Kelvin. Using the infrared detector at temperatures above 77 Kelvin can reduce burdens on cooling the device.

What is desired is to provide a semiconductor light receiving device capable of reducing the level of carriers, which is referred to as dark current, detected during operation with no light incidence.

A description will be given of examples according to the embodiment below.

A semiconductor light receiving device according to an example includes (a) a supporting base including an n-type semiconductor region; and (b) a photodiode structure disposed on the supporting base, the photodiode structure including a barrier structure, a light absorbing layer, and a p-type semiconductor region. The light absorbing layer includes III-V compound semiconductor. The III-V compound semiconductor of the light absorbing layer has a bandgap allowing the light absorbing layer to detect infrared light. The barrier structure includes a first spacer layer, a first barrier layer, and a second spacer layer. The barrier structure enables an electron barrier, and the p-type semiconductor region, the light absorbing layer, the first spacer layer, the first barrier layer, the second spacer layer, and the n-type semiconductor region being arranged in order along a direction of a first axis.

The semiconductor light receiving device provides the light absorbing layer with semiconductor of a narrow bandgap. The narrow bandgap of the light absorbing layer allows thermal excitation dependent upon the operating temperature to generate electron-hole pairs. Electrons in the electron-hole pairs (E, H) move from the light absorbing layer toward the n-type semiconductor region. The light absorbing layer is separated from n-type semiconductor region by the first barrier layer, which works as a barrier to electrons moving toward the n-type semiconductor region, so that the first barrier layer prevents a part of the thermally excited electrons from reaching the n-type semiconductor region without climbing over the electron barrier, which results in a reduction in dark current. In addition, the semiconductor light receiving device generates photo carriers in the depletion layer, which is formed at both sides of the pn-junction, in the light absorbing layer in response to the incident light LIN. A part of electrons in the photo carriers can climb over the electron barrier of the first barrier layer and then drift to the n-type semiconductor region.

In the semiconductor light receiving device according to an example, the first spacer layer and the second spacer layer have a p-type conductivity and an n-type conductivity, respectively.

The semiconductor light receiving device allows the first spacer semiconductor layer and the second spacer semiconductor layer, which are provided with the p-type conductivity and the n-type conductivity, respectively, so that the first spacer semiconductor layer and the second spacer semiconductor layer have opposite conductivities to form a pn-junction in the barrier structure. The pn-junction, formed by the first spacer semiconductor layer and the second spacer semiconductor layer, allows the barrier structure to facilitate recombination of electrons that do not go over the first barrier layer to accumulate therein.

In the semiconductor light receiving device according to an example, the photodiode structure has a semiconductor mesa. The semiconductor mesa includes the p-type semiconductor region and the light absorbing layer. The supporting base and the semiconductor mesa are arranged along the direction of the first axis. The barrier structure further includes a control electrode, and the control electrode is connected to the first spacer layer.

If necessary, the semiconductor light receiving device may provide the barrier structure with a control electrode, which is independent of the anode and cathode electrodes, connected to the first spacer semiconductor layer. The application of a voltage to the control electrode produces an electric field in the barrier structure, and the electric field is variable in response to a difference in potential between the control electrode and the cathode electrode. The first barrier layer enables the electric field therein to vary the height of the electron barrier located between the first spacer semiconductor layer and the second spacer semiconductor layer.

In the semiconductor light receiving device according to an example, the light absorbing layer has a superlattice structure of the III-V compound semiconductor.

The light absorbing layer has either a superlattice structure or a bulk layer of the III-V compound semiconductor. Alternatively, the light absorbing layer has both a superlattice structure and a bulk layer of the III-V compound semiconductor.

A light detecting apparatus according to another example of the present embodiment includes: a semiconductor light receiving device; and a thermal source varying an operating temperature of the semiconductor light receiving device.

The thermal source is coupled to the semiconductor light receiving device to be operable to define the operating temperature of the light absorbing layer.

In the light detecting apparatus according to an example of the present embodiment, the thermal source is operable to define the operating temperature larger than 77 degrees in Kelvin. The thermal source may include a cooler allowing the operating temperature of the semiconductor light receiving device to be more than 77 Kelvin with, for example, liquid nitrogen, and if needed, the operating temperature may be not more than 210 Kelvin. In particular, the operating temperature of the semiconductor light receiving device may ranges from 77 to 210 Kelvin.

Alternatively, the thermal source is operable to define the operating temperature larger not more than 77 degrees in Kelvin.

Teachings of the present embodiment can be readily understood by considering the following detailed description with reference to the accompanying drawings shown as examples. Referring to the accompanying drawings, a semiconductor light receiving device, and a method for fabricating a semiconductor light receiving device according to examples of the present embodiment will be described below. To facilitate understanding, identical reference numerals are used, where possible, to designate identical elements that are common to the figures.

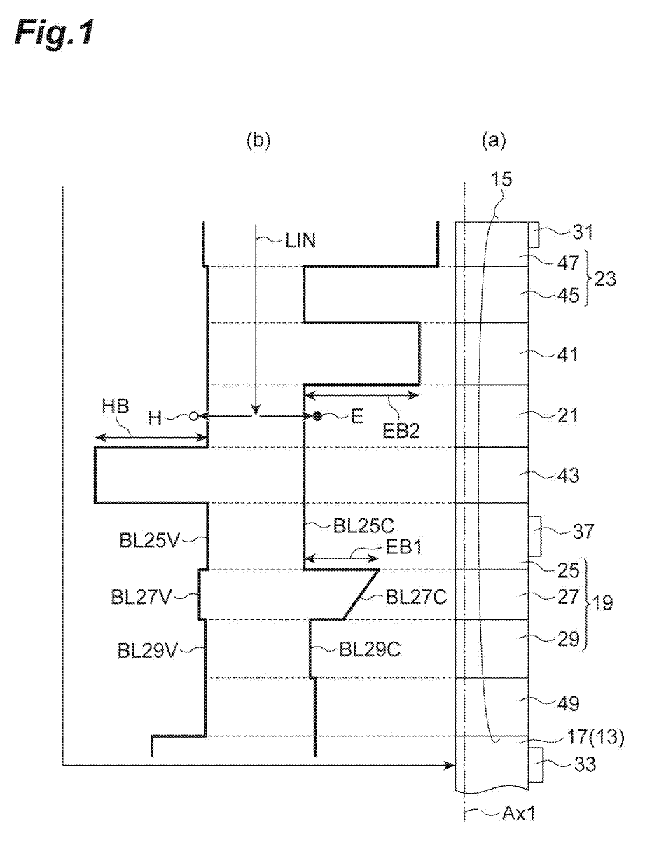

FIG. 1 is a schematic view illustrating the structure of a semiconductor light receiving device and a band diagram of the structure, which are shown in parts (a) and (b) thereof, respectively. The semiconductor light receiving device 11 includes a supporting base 13 and a photodiode structure 15. The supporting base 13 includes an n-type semiconductor region 17. The supporting base 13 mounts the photodiode structure 15 thereon, and specifically, the photodiode structure 15 is disposed on the n-type semiconductor region 17 of the supporting base 13. The photodiode structure 15 includes a barrier structure 19, a light absorbing layer 21, and a p-type semiconductor region 23. The barrier structure 19 can form an electron barrier EB1, and the light absorbing layer 21 has a bandgap allowing the light absorbing layer 21 to be sensitive to infrared light. Such a bandgap in the light absorbing layer 21 can be formed by III-V compound semiconductor that can provide the light absorbing layer 21 with a band structure allowing the absorption of light of infrared wavelengths. Specifically, the light absorbing layer 21 may have a superlattice structure and/or a bulk semiconductor to detect the infrared wavelengths.

The electron barrier EB1 can be created by the barrier structure 19. Specifically, the barrier structure 19 includes a first spacer semiconductor layer 25, a first barrier layer 27, and a second spacer semiconductor layer 29. In the semiconductor photodetector 11, the light absorbing layer 21, the first spacer semiconductor layer 25, the first barrier layer 27, and the second spacer semiconductor layer 29 are arranged in the direction of the first axis Ax1, and specifically, the p-type semiconductor region 23, the light absorbing layer 21, the first spacer semiconductor layer 25, the first barrier layer 27, the second spacer semiconductor layer 29, and the n-type semiconductor region 17 are arranged in the direction of the first axis Ax1.

The semiconductor light receiving device 11 uses semiconductor with a narrow bandgap thereof that can detect infrared light, and specifically, the semiconductor light receiving device 11 is used at an operating temperature, which determines the level of thermal excitation, generating electron-hole pairs, because of the narrow bandgap of the light absorbing layer 21. Electrons among the electron-hole pairs drift toward the n-type semiconductor region 17. The first barrier layer 27, which is disposed between the light absorbing layer 21 and the n-type semiconductor region 17, works as a barrier (EB1) to electrons moving toward the n-type semiconductor region 17. The light absorbing layer 21 can generate carriers (E and H) through thermal excitation. A certain amount of electrons among the electron hole pairs thus generated cannot get over the electron barrier EB1, leading to a reduction in dark current. Incidentally, the light absorbing layer 21 also generates optical carriers (E and H) in the depletion layer of the pn-junction in response to the incidence of the light LIN. A certain amount of electrons in the optical carriers can go over the electron barrier EB1 of the first barrier layer 27 into photocurrent, and drifts into the n-type semiconductor region 17. The electron barrier EB1 may have a height of, for example, 100 to 300 meV.

In the embodiment, the first pacer semiconductor layer 25 and the second spacer semiconductor layer 29 may have opposite conductivities, for example, a p-type conductivity and a n-type conductivity, respectively.

The semiconductor light receiving device 11 allows the barrier structure 19 to have a pn-junction which the first spacer semiconductor layer 25 of the p-type conductivity and the second spacer semiconductor layer 29 of the n-type conductivity form, so that the barrier structure 19 has a built-in potential associated with the pn-junction. The first spacer semiconductor layer 25 is provided with a conductivity type opposite to that of the second spacer semiconductor layer 29 to facilitate recombination of the electrons that still stay in the first barrier layer 27.

The semiconductor light receiving device 11 includes an anode electrode 31 and a cathode electrode 33. The anode electrode 31 is connected to the photodiode structure 15, specifically to the p-type semiconductor region 23. The cathode electrode 33 is connected to the supporting base 13, specifically the n-type semiconductor region 17.

The first barrier layer 27 includes a first type-II superlattice structure SL1 having an energy level BL27C in the conduction band, and the energy level BL27C is higher than that of the light absorbing layer 21. The first type-II superlattice structure SL1 has an energy level BL27V in the valence band. The first spacer semiconductor layer 25 has an energy level BL25C in the conduction band and an energy level BL25V in the valence band. The second spacer semiconductor layer 29 has an energy level BL29C in the conduction band, and has an energy level BL29V in the valence band.

In the conduction band, the energy level BL27C of the first barrier layer 27 is higher than the energy level BL25C of the first spacer semiconductor layer 25, and is higher than the energy level BL29C of the second spacer semiconductor layer 29. The difference between the energy levels BL27V and BL25V in the valence band is smaller than the difference between the energy levels BL25C and BL27C in the conduction band. The difference between the energy levels BL27V and BL29V in the valence band is smaller than the difference between the energy levels BL27C and BL29C in the conduction band.

If necessary, the semiconductor light receiving device 11 may further include a control electrode 37 independently of the anode electrode 31 and the cathode electrode 33. The control electrode 37 is disposed on the barrier structure 19, and is connected to the first spacer semiconductor layer 25, allowing the control electrode 37 to produce an electric field in the barrier structure 19, and the electric field has a magnitude in accordance with the potential difference between the control electrode 37 and the cathode electrode 33. The production of the electric field in the first barrier layer 27 can control the height of the electron barrier between the first and second spacer semiconductor layers 25 and 29.

Alternatively, the semiconductor light receiving device 11 may not be provided with the control electrode 37. The barrier structure 19 has one interface between the first barrier layer 27 and the first spacer semiconductor layer 25 and another interface between the first barrier layer 27 and the second spacer semiconductor layer 29. These interfaces have respective band offsets, which are determined by the semiconductor materials and laminate structure of the first and second spacer semiconductor layers 25 and 29 and the first barrier layer 27 at the interfaces, and without the control electrode 37, the band offsets defines the electron barrier of the barrier structure 19.

If necessary, the semiconductor light receiving device 11 is provided with a barrier layer provided at least one of between the light absorbing layer 21 and the p-type semiconductor region 23 and between the n-type semiconductor region 17 and the light absorbing layer 21. In the embodiment, the semiconductor light receiving device 11 includes a second barrier layer 41 and a third barrier layer 43. Specifically, the second barrier layer 41 is disposed between the light absorbing layer 21 and the p-type semiconductor region 23 to produce the electron barrier EB2. The third barrier layer 43 is disposed between the light absorbing layer 21 and the n-type semiconductor region 17, more specifically between the light absorbing layer 21 and the barrier structure 19, to produce a hole barrier. The electron barrier EB1 of the first barrier layer 27 is smaller than the electron barrier EB2 of the second barrier layer 41. The third barrier layer 43 is provided with a hole barrier HB larger than the electron barrier EB1 of the first barrier layer 27. The second barrier layer 41 has a superlattice structure which includes first semiconductor layers 41a and second semiconductor layers 41b, which are alternately arranged to form a superlattice. The third barrier layer 43 has a superlattice structure which includes first semiconductor layers 43a and second semiconductor layers 43b, which are alternately arranged to form a superlattice.

The semiconductor light receiving device 11 provides the second barrier layer 41 with an offset producing an electron barrier higher than the electron barrier EB1 of the first barrier layer 27. The low electron barrier EB17 allows photo carriers from the light absorbing layer 21 to climb over the first barrier layer 27, so that the photo carriers thus climbed turn into photocurrent, while the high electron barrier EB2 of the second barrier layer 41 can firmly stop thermally excited carriers, which may turn into dark current. In addition, the semiconductor light receiving device 11 provides the third barrier layer 43 with a hole barrier having an offset larger than the electron barrier EB17 of the first barrier layer 27. The third barrier layer 43 can prevent the climbing-over of the thermally excited carriers using the high hole barrier HB.

The first spacer semiconductor layer 25 of the barrier structure 19 may have a smaller thickness than that of the light absorbing layer 21. Specifically, the semiconductor light receiving device 11 may provide the first spacer semiconductor layer 25 with a thin-film region between the light absorbing layer 21 and the n-type semiconductor region 17, and may provide the thin-film region with a p-type conductivity, so that the p-type thin region forms the other pn-junction with the barrier structure 19.

Further, the first spacer semiconductor layer 25 of the barrier structure 19 may be provided with a bandgap smaller than that of the light absorbing layer 21. The smaller bandgap of the first spacer semiconductor layer 25 facilitates recombination of electrons that come from the light absorbing layer 21 to fail to go over the first barrier layer 28.

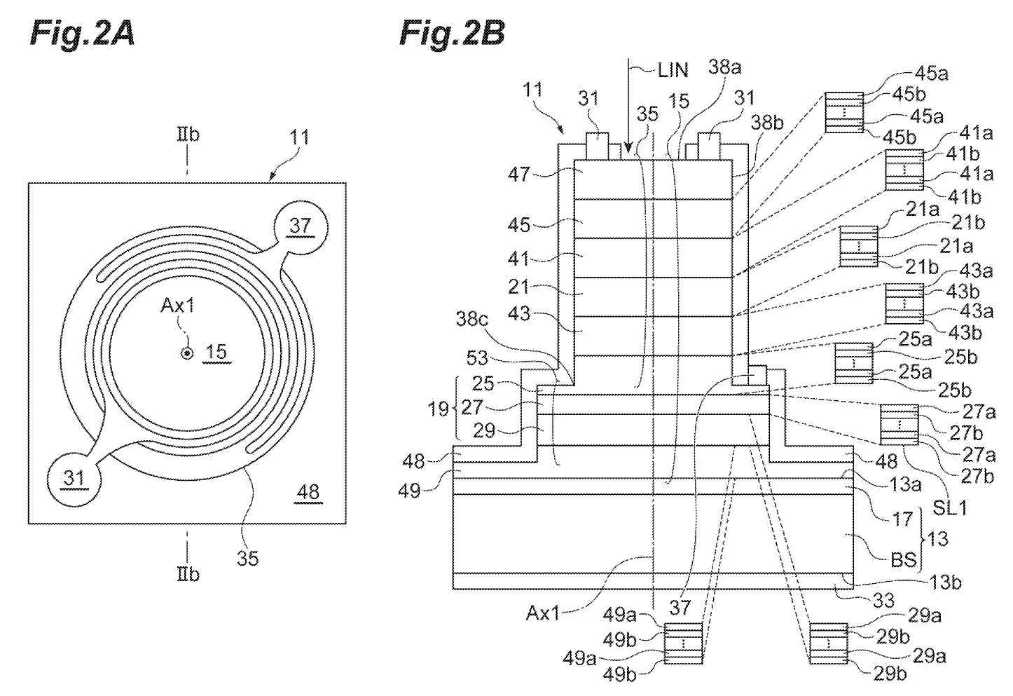

FIG. 2A is a schematic plan view showing a semiconductor light receiving device according to the embodiment, and FIG. 2B is a schematic cross sectional view taken along line IIb-IIb shown in FIG. 2A. As shown in FIGS. 2A and 2B, the supporting base 13 includes a principal face 13a and a back face 13b. The photodiode structure 15 has a semiconductor mesa 35 on the principal face 13a of the supporting base 13. The supporting base 13 and the semiconductor mesa 35 are arranged along the direction of the first axis Ax1. The semiconductor mesa 35 includes the light absorbing layer 21 and the p-type semiconductor region 23, and may further include a portion of the first spacer semiconductor layer 25 of the barrier structure 19 in the embodiment. Specifically, the semiconductor mesa 35 is provided with not only the light absorbing layer 21 and the p-type semiconductor region 23 but also the second and third barrier layers 41 and 43. In this embodiment, the p-type semiconductor region 23 (and the second barrier layer 41), the light absorbing layer 21, and the third barrier layer 43 are arranged along the direction of the first axis Ax1.

In the embodiment, the p-type semiconductor region 23 may include not only the second barrier layer 41 but also a p-type type-II superlattice structure 45 and a p-type cap layer 47. The p-type type-II superlattice structure 45 includes first semiconductor layers 45a and second semiconductor layers 45b, which are alternately arranged to form a superlattice. In the embodiment, the p-type cap layer 47 is made of a bulk semiconductor. The p-type cap layer 47 in the p-type semiconductor region 23 makes contact with the anode electrode 31.

In the embodiment, the n-type semiconductor region 17 includes a type-II superlattice structure 49 and a bulk semiconductor layer 51, which have an n-type conductivity. The n-type type II superlattice structure 49 includes first semiconductor layers 49a and second semiconductor layers 49b, which are alternately arranged to form a superlattice. The cathode electrode 33 can be provided on either the n-type type-II superlattice structure 49 or the back side 13b of the supporting base 13.

The photodiode structure 15 may have a terrace 53 in the semiconductor laminate, and the terrace 53 is disposed on the supporting base and mounts the semiconductor mesa MS. The semiconductor mesa MS has a top face 38a, a side face 38b and a bottom 38c, and the side face 38b extends in the direction of the first axis Ax1 from the top face 38a to the bottom 38c.

The barrier structure 19 is disposed over the terrace 53 and the semiconductor mesa MS. The semiconductor mesa MS includes an upper part of the barrier structure 19, and the terrace 53 may include the remainder of the barrier structure 19.

Specifically, the semiconductor mesa MS is provided with the upper part of the first spacer semiconductor layer 25, and the terrace 53 may be provided with the lower part of the first spacer semiconductor layer 25 in addition to the first barrier layer 27 and the second spacer semiconductor layer 29. The control electrode 37 can be disposed on the terrace 53 and makes contact with the first spacer semiconductor layer 25, specifically the top face of the lower part of the first spacer semiconductor layer 25 outside the semiconductor masa. The cathode electrode 33 may be in contact with the back face 13b of the supporting base 13.

Alternatively, the semiconductor mesa MS may include the first spacer semiconductor layer 25, the first barrier layer 27, and a portion of the second spacer semiconductor layer 29 in the barrier structure 19, and the terrace 53 may include the remaining part of the second spacer semiconductor layer 29. The semiconductor light receiving device 11 is provided with no control electrode 37. The cathode electrode 33 can be disposed on the terrace 53 and makes contact with the second spacer semiconductor layer 29, specifically the top face of the lower part of the second spacer semiconductor layer 29 outside the semiconductor masa.

If possible, the semiconductor light receiving device 11 may include no terrace 53, and the semiconductor mesa MS includes all of the layers in the barrier structure 19. The semiconductor light receiving device 11 excludes the control electrode 37.

The first spacer semiconductor layer 25 may have a type-II superlattice structure. This type-II superlattice structure includes first semiconductor layers 25a and second semiconductor layers 25b, which are alternately arranged to form a superlattice. Providing the first spacer semiconductor layer 25 with the superlattice structure allows the first spacer semiconductor layer 25 to have a band structure enabling the energy difference (between the conduction and valence bands) smaller than the energy difference between the conduction and valence bands in the light absorbing layer which carriers propagate, so that the semiconductor light receiving device 11 provides the first spacer semiconductor layer 25 with a bandgap, which is formed by the superlattice structure, smaller than that of the light absorbing layer. This smaller bandgap facilitates recombination of electrons, which miss passing the first barrier layer 27 to be accumulated in the first spacer semiconductor layer 25. Specifically, the first spacer semiconductor layer 25 may include, for example, a p-type InAs/GaSb superlattice.

The second spacer semiconductor layer 29 may have a type-II superlattice structure. The superlattice structure of the second spacer semiconductor layer 29 includes first semiconductor layers 29a and second semiconductor layers 29b, which are alternately arranged to form a superlattice. Providing the second spacer semiconductor layer 29 with the superlattice structure allows the second spacer semiconductor layer 29 to have a band structure enabling the energy difference (between the conduction and valence bands) larger than the energy difference between the conduction and valence bands of the first spacer semiconductor layer 25 in which carriers may accumulate, so that the semiconductor light receiving device 11 provides the second spacer semiconductor layer 29 with a bandgap, which is formed by the superlattice structure thereof, larger than that of the first spacer semiconductor layer 25. This larger bandgap facilitates controlling of the width of the depletion layer in the barrier structure 19. Specifically, the second spacer semiconductor layer 29 may include, for example, an InAs/GaSb superlattice having an n-type conductivity.

The first barrier layer 27 has a type-II superlattice structure. The superlattice structure of the first barrier layer 27 includes first semiconductor layers 27a and second semiconductor layers 27b, which are alternately arranged to form a superlattice. In particular, the first barrier layer 27 may be provided with the first superlattice structure of an InAs/GaSb superlattice. The InAs/GaSb superlattice allows the first barrier layer 27 to form a potential barrier to electron in the conduction band and substantially no potential barrier to hole in the valence band.

The light absorbing layer 21 has a type-II superlattice structure. The superlattice structure of the light absorbing layer 21 includes first semiconductor layers 21a and second semiconductor layers 21b, which are alternately arranged to form a superlattice. Specifically, the light absorbing layer 21 may include an InAs/GaSb superlattice. Providing the light absorbing layer 21 with the InAs/GaSb superlattice allows the semiconductor light receiving device 11 to have a photo-sensitivity in an infrared wavelength range (for example, 3 to 15 micrometers in wavelength).

An exemplary semiconductor light receiving device 11

Base BS in the supporting base 13: GaSb substrate having an n-type conductivity

N-type semiconductor region 17 in the supporting base 13: GaSb epitaxial layer (with a thickness of 500 nm and a dopant concentration of 1 to 3×10¹⁸ cm⁻³) having an n-type conductivity

Photodiode structure 15

Type-II superlattice structure 49: InAs/GaSb superlattice (with a thickness of 350 nm and a dopant concentration of 1×10¹⁸ cm⁻³) having an n-type conductivity

Barrier structure 19

First spacer semiconductor layer 25: InAs/GaSb superlattice (with a thickness of 300 nm and a dopant concentration of 1 to 2×10¹⁸ cm⁻³) having a p-type conductivity

First barrier layer 27: InAs/GaSb superlattice (with a thickness of 60 nm and a dopant concentration of 0.1 to 1×10¹⁶ cm⁻³) having a p-type conductivity

Second spacer semiconductor layer 29: InAs/GaSb superlattice (with a thickness of 160 nm and a dopant concentration of 0.1 to 1×10¹⁶ cm⁻³) having an n-type conductivity

Third barrier layer 43 (acting as a hole barrier layer): InAs/GaSb superlattice (with a thickness of 300 nm and a dopant concentration of 1 to 2×10¹⁶ cm⁻³) having an n-type conductivity

Light absorbing layer 21: InAs/GaSb superlattice (with a thickness of 1000 nm and a dopant concentration of 0.1 to 1×10¹⁶ cm⁻³) having a p-type conductivity

Second barrier layer 41 (electron barrier layer): undoped InAs/GaSb superlattice (with a thickness of 300 nm)

P-type semiconductor region 23

P-type type-II superlattice structure 45: InAs/GaSb superlattice (with a thickness of 250 nm and a dopant concentration of 1 to 2×10¹⁷ cm⁻³) having a p-type conductivity

P-type cap layer 47: GaSb bulk semiconductor (with a thickness of 200 nm and a dopant concentration of 1 to 3×10¹⁸ cm⁻³) having a p-type conductivity

Protective film 48: silicon-based inorganic insulating film (made of silicon oxide, SiO₂; and having a thickness of 100 to 300 nm)

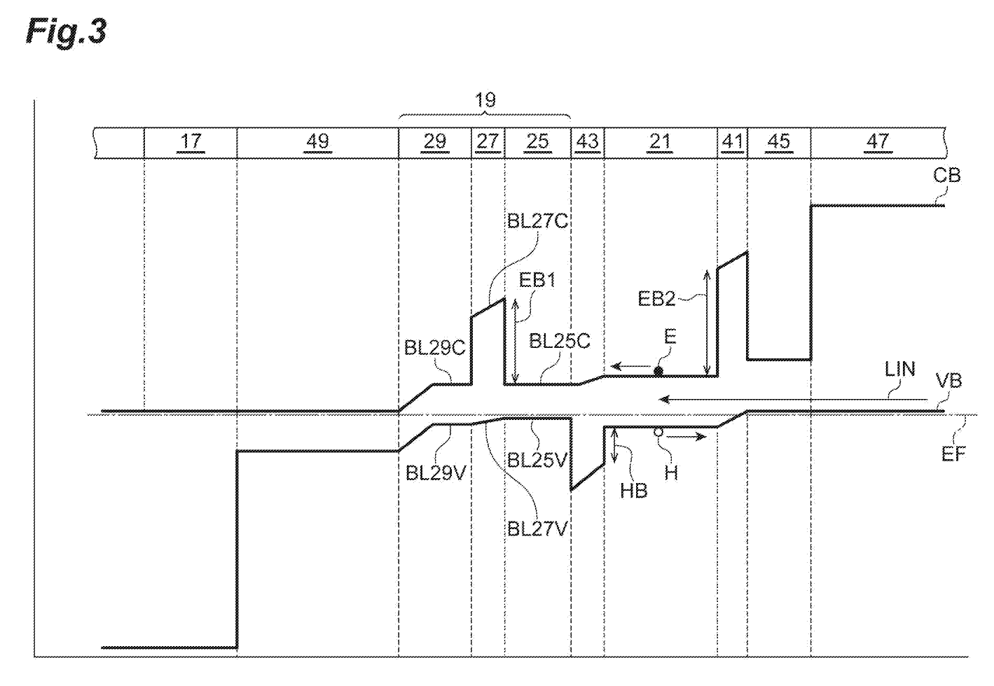

FIG. 3 illustrates a band diagram of the semiconductor light receiving device 11. Referring to FIG. 3, the supporting base 13 and the photodiode structure 15 has a conduction band CB and a valence band VD, and the Fermi level EF is shown therein. The superlattice structures, which exclude the bulk semiconductor region, in the semiconductor light receiving device 11 have respective electron energy levels in the conduction band CB, and respective hole energy levels in the valence bands VD.

The light absorbing layer 21 is disposed between the second barrier layer 41 (acting as an electron barrier layer) and the third barrier layer 43 (acting as a hole barrier layer). The light absorbing layer 21 and the third barrier layer 43 (the hole barrier layer) are disposed between the second barrier layer 41 (the electron barrier layer) and the barrier structure 19. The first barrier layer 27 provides the barrier structure 19 with an electron barrier EB1 of, for example, about 300 meV. The second barrier layer 41 (the electron barrier layer) has an electron barrier height of, for example, about 100 to 200 meV, which is larger than the electron barrier EB1. The third barrier layer 43 (the hole barrier layer) has a hole barrier height of about 100 to 200 meV, which is larger than the electron barrier EB1. The semiconductor light receiving device 11 receives electric power from a second power source PS2, which is connected to between the cathode electrode 33 and the control electrode 37.

Name of characteristic curve, Voltage (V) applied to the control electrode

C1, zero

C2, 150 mV (the bias voltage is variable in the range of 50 to 150 mV as required)

C3, 300 mV (the bias voltage is variable in the range 150 to 300 mV as request)

“BVin” represents a built-in potential.

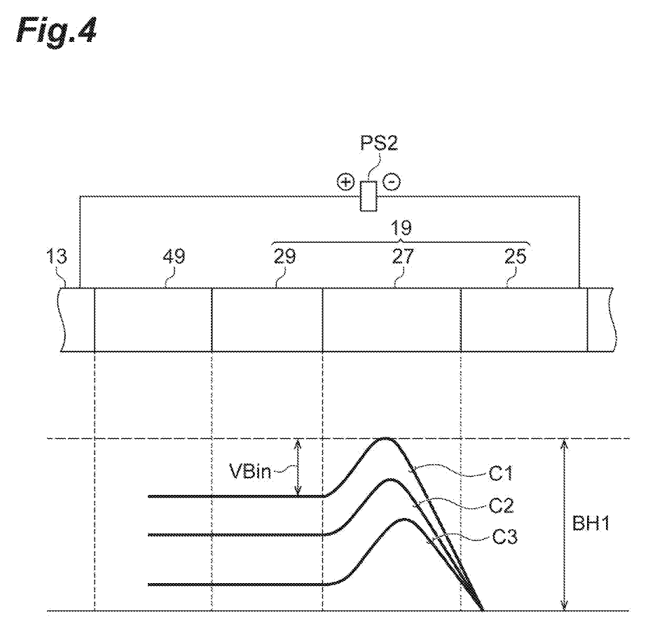

FIG. 4 is a drawing showing potential variations of the electron barrier EB1, which is dependent on the voltage applied to the control electrode, of the barrier structure 19. Specifically, the first spacer semiconductor layer 25 receives a positive voltage with reference to the potential of the n-type type-II superlattice structure 49. The electron barrier EB1 of the first barrier layer 27 becomes lower as the applied voltage increases.

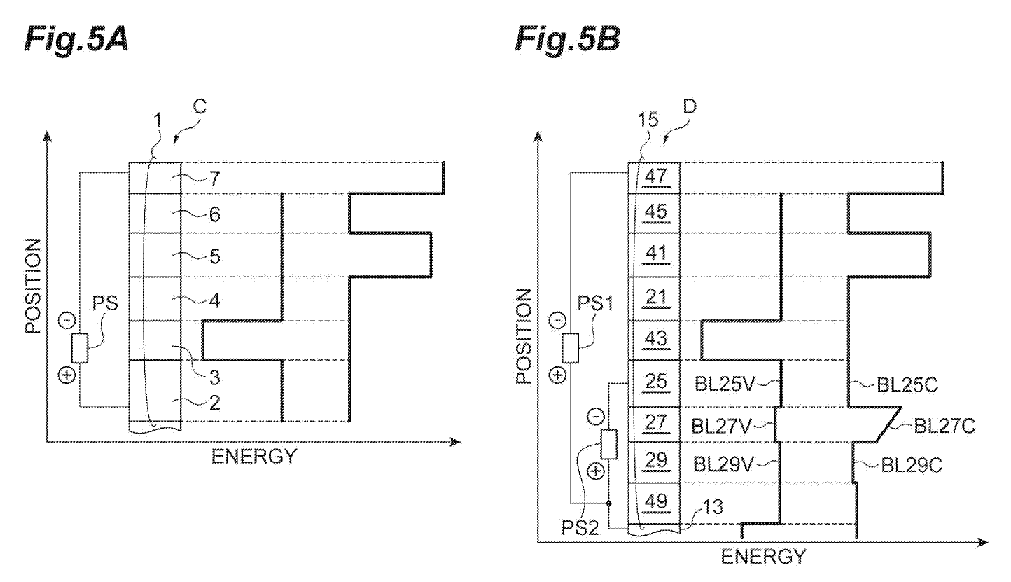

FIGS. 5A and 5B are schematic views each showing the photodiode structure and the band diagram of the experimental example. In particular, FIG. 5A illustrates the photodiode structure and the band diagrams of the semiconductor light receiving device C, and FIG. 5B illustrates the photodiode structure and the band diagram of the semiconductor light receiving device D. The semiconductor light receiving devices C and D each are connected to a first power source PS1 across the anode and the cathode thereof, and the semiconductor light receiving device D is connected to a second power source PS2 across the cathode electrode 33 and the control electrode 37.

Structure of semiconductor photodetector C shown in FIG. 5A

Photodiode Structure 1

N-type type-II superlattice structure 2: InAs/GaSb superlattice (with a thickness of 350 nm and a dopant concentration of 1×10¹⁸ cm⁻³) having an n-type conductivity

Hole barrier layer 3: InAs/GaSb superlattice (with a thickness of 300 nm and a dopant concentration of 1 to 2×10¹⁶ cm⁻³) having an n-type conductivity

Light absorbing layer 4: InAs/GaSb superlattice (with a thickness of 1000 nm and a dopant concentration of 0.1 to 1×10¹⁶ cm⁻³) having a p-type conductivity

Electron barrier layer 5: undoped InAs/GaSb superlattice (with a thickness of 300 nm)

P-Type Semiconductor Region

P-type type-II superlattice structure 6: InAs/GaSb superlattice (with a thickness of 250 nm and a dopant concentration of 1 to 2×10¹⁷ cm⁻³) having a p-type conductivity

P-type cap layer 7: GaSb bulk (with a thickness of 200 nm and a dopant concentration of 1 to 3×10¹⁸ cm⁻³) having a p-type conductivity

Structure of Semiconductor Photodetector D Shown in FIG. 5B

Photodiode Structure 15

N-type type-II superlattice structure 49: InAs/GaSb superlattice (with a thickness of 350 nm and a dopant concentration of 1×10¹⁸ cm⁻³) having an n-type conductivity

Barrier Structure 19

First spacer semiconductor layer 25: InAs/GaSb superlattice (with a thickness of 300 nm and a dopant concentration of 1×10¹⁸ cm⁻³) having a p-type conductivity

First barrier layer 27: InAs/GaSb superlattice (with a thickness of 60 nm and a dopant concentration of 0.1 to 1×10¹⁶ cm⁻³) having a p-type conductivity

Second spacer semiconductor layer 29: InAs/GaSb superlattice (with a thickness of 160 nm and a dopant concentration of 1×10¹⁶ cm⁻³) having an n-type conductivity

Third barrier layer 43: InAs/GaSb superlattice (with a thickness of 300 nm and a dopant concentration of 1×10¹⁶ cm⁻³) having an n-type conductivity

Light absorbing layer 21: InAs/GaSb superlattice (with a thickness of 1000 nm and a dopant concentration of 0.1×10¹⁶ cm⁻³) having a p-type conductivity

Second barrier layer 41: undoped InAs/GaSb superlattice (with a thickness of 300 nm)

P-type semiconductor region 23

P-type type-II superlattice structure 45: InAs/GaSb superlattice (with a thickness of 250 nm and a dopant concentration of 1 to 2×10¹⁷ cm⁻³) having a p-type conductivity

P-type cap layer 47: GaSb bulk semiconductor (with a thickness of 200 nm and a dopant concentration of 1 to 3×10¹⁸ cm⁻³) having a p-type conductivity

In order to measure the dark current characteristics of the semiconductor light receiving device 11, a light detecting apparatus is prepared which includes a container, the semiconductor light receiving device and the thermal source. The thermal source can vary an operating temperature of the semiconductor light receiving device 11.

In particular, the semiconductor light receiving device 11 is coupled to the thermal source in the container which can hermetically seal the semiconductor light receiving device 11, so that the thermal source and the container keep the operating temperature stabilized.

The thermal source, which is operable to define the operating temperature of the light absorbing layer, is coupled to the semiconductor light receiving device.

The container has three terminals for the anode, cathode and control electrodes, and the semiconductor light receiving device in the container is connected to the respective terminals at the anode, cathode and control electrodes (31, 33, and 37) thereof.

Specifically, the thermal source is operable to define the operating temperature larger than 77 degrees in Kelvin. The thermal source may include a controllable cooler, which can make the operating temperature of the semiconductor light receiving device more than 77 Kelvin with a coolant, such as liquid nitrogen, and a heater heating the cooling medium, and if needed, the operating temperature may be not more than 210 Kelvin. In particular, the operating temperature of the semiconductor light receiving device may ranges from 77 to 210 Kelvin in the measurement system.

Alternatively, the thermal source may be operable to define the operating temperature larger not more than 77 degrees in Kelvin.

The light detecting apparatus thus prepared is connected to a power supply and a parametric analyzer to measure the dark current characteristics of the semiconductor light receiving device 11 at desired operating temperatures, which is controllable with the thermal source.

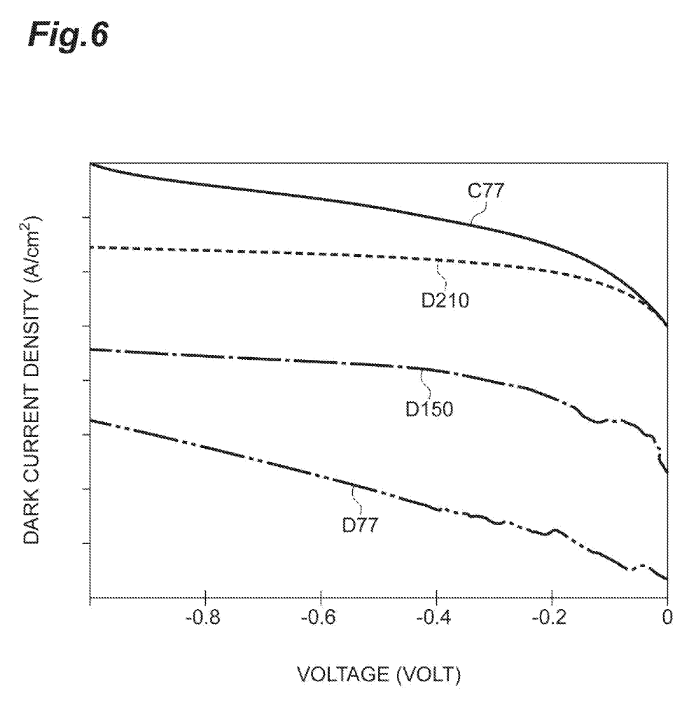

FIG. 6 shows the dark current characteristics of the semiconductor light receiving devices C and D. The horizontal axis indicates the voltage between the anode and the cathode, and the vertical axis indicates the measured current density. In the measurement of the semiconductor light receiving device D, zero voltage is applied to the control electrode is (zero bias condition in the second power source PS2). The semiconductor light receiving device C has a dark current characteristic curve “C77” at an absolute temperature of 77 degrees in Kelvin. The semiconductor light receiving device D has dark current characteristic curves “D77”, “D150” and “D210” at absolute temperatures of 77 Kelvin, 150 Kelvin and 210 Kelvin, respectively. In terms of dark current, the semiconductor light receiving device D in the temperature range of 77 to 210 degrees in Kelvin is superior to that of the semiconductor light receiving device C (at the absolute temperature of 77 Kelvin).

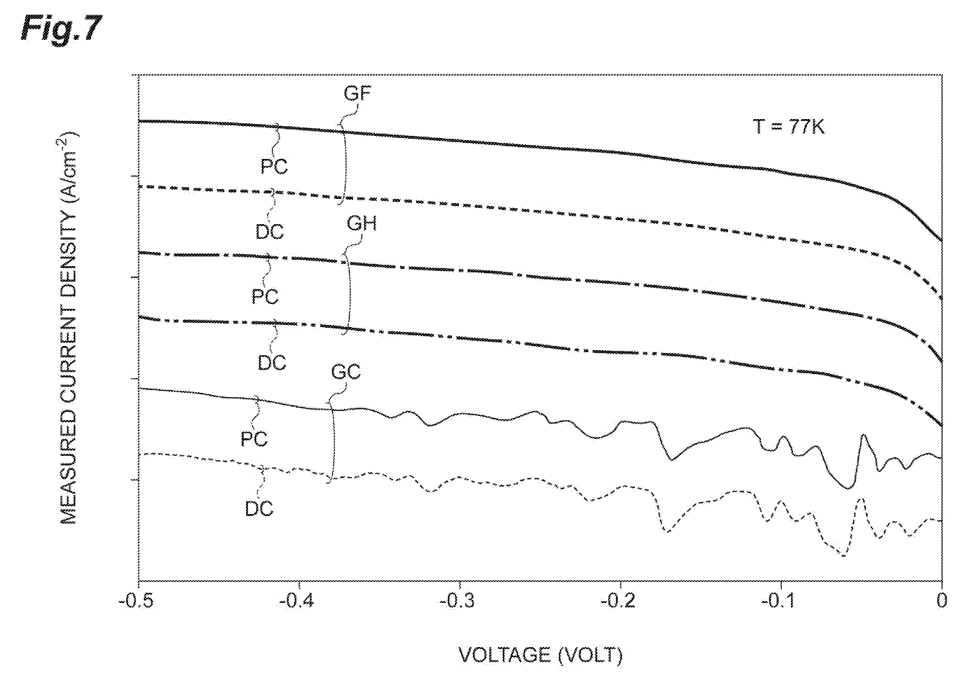

FIG. 7 shows the dark current characteristic DC and the photo response characteristics PC of the semiconductor light receiving device D. The horizontal axis indicates the anode-cathode voltage, and the vertical axis indicates the measured current density. The dark current characteristic and the photo response characteristic are measured at an absolute temperature of 77 Kelvin. The measurement system uses voltages of −0.5, −0.3 and 0.0 volts, applied to the control electrode, to produce dark current characteristics DC and optical response characteristics PC, which are represented in accordance with the applied control voltage by symbols “GF”, “GH” and “GC”, respectively. These experiments show that applying a voltage to the control electrode can reduce the level of the dark current in the semiconductor light receiving device D. Further, the semiconductor light receiving device D, which is operable at the level of the reduced dark current (with a voltage applied to the control electrode), can be used to generate photo carriers in response to the incidence of light, changing the photo carriers into the photocurrent.

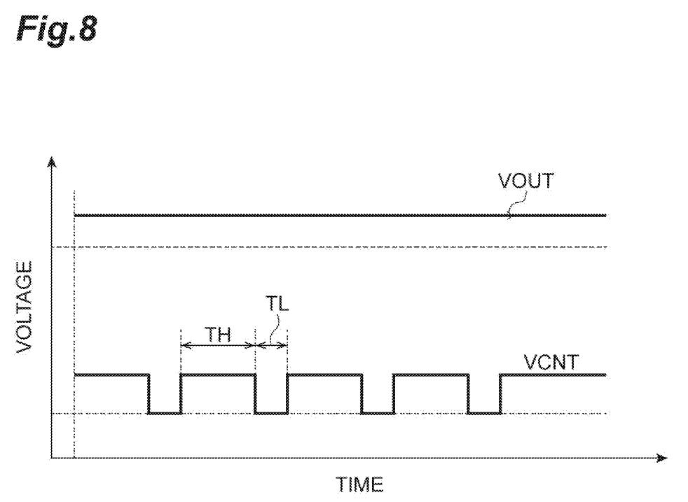

FIG. 8 is an exemplary time chart showing waveforms of the voltage (VCNT), applied to the control electrode of the semiconductor photodetector D, and the voltage (VOUT) applied to the anode and the cathode, in the measurement of FIG. 7.

Voltage (VOUT) applied to anode and cathode: −1.0 volt (continuously applied voltage).

Voltage applied to the control electrode (VCNT): −0.3 volts (pulsed voltage)

High-level period of pulse signal (TH): 1 microsecond to 1 milliseconds

Low-level period of pulse signal (TL): 1 nanosecond to 1 microsecond

As described above, the present embodiment provides the semiconductor light receiving device with the barrier structure 19, which can reduce the dark current detected during operation without light incidence, effective in either the presence or the absence of the control voltage, or the presence and absence of the control voltage.

Subsequently, a description will be given of a method for fabricating the semiconductor light receiving device 11 below. Epitaxial films for the photodiode structure 15 are grown on the GaSb wafer by molecular beam epitaxy. Specifically, a semiconductor laminate is formed which includes the following semiconductor films: an n-type InAs/GaSb superlattice for the n-type type-II superlattice structure 49; an n-type InAs/GaSb superlattice for the second spacer semiconductor layer 29; a p-type InAs/GaSb superlattice for the first barrier layer 27; a p-type InAs/GaSb superlattice for the first spacer semiconductor layer 25; an n-type InAs/GaSb superlattice for the third barrier layer 43; a p-type InAs/GaSb superlattice for the light absorbing layer 21; an undoped InAs/GaSb superlattice for the second barrier layer 41; a p-type InAs/GaSb superlattice for the p-type superlattice structure 45; and a p-type GaSb film for the p-type cap layer 47. An insulating film mask is formed on the semiconductor laminate and defines the shape of the mesa. The semiconductor laminate is etched with the insulating mask to form a semiconductor mesa, and if necessary, a semiconductor stage may be formed by etching the semiconductor laminate with the insulating mask having an additional pattern, which surrounds the pattern for the semiconductor mesa. The insulating mask is removed after the etching, and thereafter a silicon-based inorganic insulating film (for example, an SiN film) is deposited on the semiconductor mesa and the semiconductor terrace. The SiN film is etched to form openings for the anode electrode and the cathode electrode (if necessary, the control electrode), and a metal film for metallization is deposited on the patterned SiN film. These steps bring the semiconductor light receiving device 11 to completion.

As seen from the above description, the present embodiment can provide a semiconductor photodetector and a semiconductor light receiving device capable of reducing dark current, which is detected with no incidence of light, during operation.

Having described and illustrated the principle of the invention in a preferred embodiment thereof, it is appreciated by those having skill in the art that the invention can be modified in arrangement and detail without departing from such principles. We therefore claim all modifications and variations coining within the spirit and scope of the following claims.

What is claimed is:

1. A semiconductor light receiving device comprising:
a supporting base including an n-type semiconductor region; and
a photodiode structure disposed on the supporting base, the photodiode structure including a barrier structure, a light absorbing layer, and a p-type semiconductor region,
the light absorbing layer including III-V compound semiconductor,
the III-V compound semiconductor of the light absorbing layer having a bandgap allowing the light absorbing layer to be sensitive to infrared light,
the barrier structure including a first spacer layer, a first barrier layer, and a second spacer layer,
the barrier structure enabling an electron barrier, and
the p-type semiconductor region, the light absorbing layer, the first spacer layer, the first barrier layer, the second spacer layer, and the n-type semiconductor region being arranged in order along a direction of a first axis.

2. The semiconductor light receiving device according to claim 1, wherein the first spacer layer and the second spacer layer have p-type and n-type conductivities, respectively.

3. The semiconductor light receiving device according to claim 1, wherein
the photodiode structure has a semiconductor mesa,
the semiconductor mesa includes the p-type semiconductor region and the light absorbing layer,
the supporting base and the semiconductor mesa are arranged along the direction of the first axis,
the barrier structure further includes a control electrode, and
the control electrode is connected to the first spacer layer.

4. The semiconductor light receiving device according to claim 1, wherein the light absorbing layer has a superlattice structure of the III-V compound semiconductor.
